(19) United States
(12) Patent Application Publication
(10) Pub. No.: US 2006/0035035 A1
(43) Pub. Date: Feb. 16, 2006

(54) Film forming method and film forming apparatus

(75) Inventor: Mitsunori Sakama, Hiratsuka (JP)

Correspondence Address: ERIC ROBINSON, PMB 955, 21010 SOUTHBANK ST., POTOMAC FALLS, VA, 20165, US

(73) Assignee: Semiconductor Energy Laboratory Co., Ltd., Atsugi-shi (JP)

(21) Appl. No.: 11/205,084

(22) Filed: Aug. 17, 2005

Related U.S. Application Data
(62) Division of application No. 09/070,908, filed on May 4, 1998, now abandoned.

(30) Foreign Application Priority Data
May 10, 1997 (JP) 9-136211
May 15, 1997 (JP) 9-140917

(51) Int. Cl. H05H 1/24; H01L 21/20

(52) U.S. Cl. 427/569; 438/485; 438/487

(57) ABSTRACT

When an amorphous silicon film is formed by a plasma CVD method, a hydrogen gas is supplied into a chamber before the start of film formation to cause discharge. In this state, film formation is not made. At the step where the discharge becomes stable, silane as a film forming gas is supplied into the chamber. At the same time, supply of the hydrogen gas is stopped. Silane is decomposed by the stable discharge, and film formation of an amorphous silicon film is made. By doing so, it is possible to eliminate the instability at the start of discharge. Film formation can be carried out in the state where the discharge is always stable. Also, in the plasma CVD method using silane as the film forming gas, supply of the silane gas is stopped in the state where the radio frequency discharge is maintained, and instead of the silane gas, the hydrogen gas as the discharge gas is supplied. For a predetermined period of time, plasma without film formation by decomposition of the hydrogen gas is formed. Since a negative self bias is applied to the formed surface in this state, negatively charged minute particles do not adhere to the formed surface. The discharge is stopped in the state where the minute particles in the atmosphere are exhausted. In this way, the state where the minute particles do not adhere to the formed surface can be made.

### BACKGROUND OF THE INVENTION

1. Field of the Invention

The present invention relates to a technique for forming a thin film by a plasma CVD method, and particularly, to a technique for forming a silicon film by using the plasma CVD method. The present invention also relates to a film forming apparatus which can carry out the film forming method.

2. Description of the Related Art

A technique for forming an amorphous silicon film by a plasma CVD method using silane as a raw material gas has been known.

This technique is used for fabricating a thin film silicon film constituting a thin film transistor (called a TFT) or a solar cell.

For example, in a case where the TFT is fabricated, a noncrystalline silicon film (amorphous silicon film) is first formed by the plasma CVD method on a glass substrate or a quartz substrate, the amorphous silicon film is patterned to form an active layer of the TFT, and the TFT is fabricated by using the active layer.

In recent years, there is a tendency for the thickness of a thin semiconductor film used for a thin film device typified by a TFT to become thinner than ever.

For example, at present, the thickness of a silicon film constituting an active layer of a TFT is about 50 nm or less.

Further, a plasma CVD method is known as a film forming method of an amorphous silicon film or a silicon oxide film.

In film formation of various thin films by the plasma CVD method, minute particles such as particles and flakes produced at the film formation become problematic.

The minute particles are mainly comprised of (1) a component obtained as a result that a reaction product formed on an inner wall or an electrode of a reaction chamber for each film formation got some energy during discharge and came loose and fall, and (2) a component produced in the vapor phase and did not contribute to the formation of a thin film. In any event, the foregoing minute particles are reaction products by a raw material gas used in the film formation.

The minute particles adhere to a formed film and causes an extreme deterioration to the film quality.

In order to solve the problem, it is effective to increase the number of times of cleaning in a chamber.

However, even if cleaning is carried out for each film formation, only the number of minute particles produced from the foregoing (1) can be decreased, and a fundamental solution can not be obtained.

Besides, since increasing the number of times of cleaning causes productivity to be lowered and an operation to be complicated, it is not preferable in view of industry.

In the circumstances that the thickness of a thin film semiconductor film tends to become thinner than ever, the uniformity of a film thickness for each lot of film formation becomes problematic.

If the thickness of a formed thin film becomes thin, a period of time for film formation naturally becomes short. Then the instability of discharge at the start of film formation becomes problematic.

As one example, a timing chart in the case of film formation of an amorphous silicon film will be shown in FIG. 2B.

Here, an example in which an amorphous silicon film is formed by using silane as a raw material gas will be described.

First, the inside of a decompression chamber is evacuated into an ultra high vacuum state. Then silane (SiH₄) is supplied into the decompression chamber at a flow rate of 100 sccm. Here, silane is supplied into the decompression chamber at the flow rate of 100 sccm so that the pressure in the decompression chamber is made 0.5 Torr.

When the pressure in the decompression chamber becomes a predetermined value, a radio frequency power source (RF power source) is turned on, so that radio frequency energy is supplied into the decompression chamber.

Film formation is carried out for a predetermined period of time. The period of time of film formation is defined as a period of time 23 of film formation. Reference numeral 21 denotes a start point of film formation, and 22 denotes an end point of film formation.

The termination of film formation is made by stopping the supply of the radio frequency power.

Although depending on conditions, a film formation rate (film formation speed) in the film formation of an amorphous silicon film by a plasma CVD method is, for example, about 0.8 nm/s.

In this case, if the thickness of the formed film is 50 nm, a film formation time is about 62.5 sec.

Although depending on conditions, a period of time of a transitional state (in this state, the discharge is unstable) at the start of discharge designated by t₁ becomes uneven within the range of about 3 sec to 8 sec.

The instability of discharge at the start of discharge is hardly dependent on the kind of gas.

In the case of the foregoing conditions, the period of time t₁ of the unstable discharge amounts to about 10% of the total period of time of film formation. Further, the period of time is not stable. That is, the period is uneven for each lot.

In such a case, the unevenness of the period of time of the unstable discharge (designated by t₁ in FIG. 2B) has a large influence on the unevenness in the thickness of a film formed for each lot.

As described above, when the thickness of a formed film becomes thin and the period of time of film formation becomes short, the influence of the unstable discharge at the start of film formation can not be neglected.

Specifically, in accordance with the difference of the period of time in which the unstable discharge continues, the difference in the film thickness for each lot becomes actualized.

### SUMMARY OF THE INVENTION

An object of the present invention is to solve the problem due to the unstable discharge at the start of film formation and to provide a technique for correcting the unevenness in the thickness of a formed film for each lot.

Another object of the present invention is to provide a technique for preventing the existence of minute particles produced at film formation by a plasma CVD method from having a bad influence on the film quality of a formed thin film.

The present invention has been made through the following process. That is, as a result of research as to when the minute particles of the above described reaction products adhere to a formed film, it has been found that the minute particles adhere to the film before and after the end point of the film formation and have a bad influence on the film quality.

The process of obtaining the above finding will be described below. In general, a plasma CVD apparatus includes a structure of parallel flat plate type as shown in FIG. 1, and includes a structure that a sample (substrate) 11 is placed on one electrode 12 maintained at ground potential and a radio frequency power source 16 is connected to the opposite other electrode 15.

FIG. 8 shows the relation of timing between the supply of a raw material gas and the radio frequency discharge (RF discharge) in a case where ordinary film formation is carried out. In the drawing, reference numeral 81 denotes a start point of film formation, 82 denotes an end point of film formation, and 83 denotes a period of time of film formation.

In general, in the state where plasma is generated by radio frequency (high frequency) discharge, a bias voltage as shown in FIG. 9 is applied between electrodes. In FIG. 9, the vertical axis indicates a relative potential, and the horizontal axis indicates a position.

The bias voltage becomes a large negative voltage at the side of the feeding electrode 15 and becomes a relatively small negative voltage at the side of the ground electrode 12.

In general, minute particles floating in the chamber become negatively charged. Thus, in the discharge, the minute particles are repelled from the electrode 12, so that the minute particles hardly adhere to the substrate placed on the electrode 12.

That is, during the film formation in FIG. 8, the minute particles scarcely adhere to the film.

However, when the discharge is ended, the applying state of the self bias as shown in FIG. 9 disappears, and in accordance with that, the minute particles fall down to the substrate and adhere onto the formed surface. Further, the minute particles adhere to the surface of the substrate (surface of the formed surface) by static electricity.

In order to solve the problems, according to an aspect of the present invention, a method of forming a silicon film, by a plasma CVD method comprises: a first step of supplying a non-silicide gas for discharge into a decompression chamber; a second step of supplying radio frequency (high frequency) energy into the decompression chamber to cause radio frequency (high frequency) discharge; a third step of supplying a silicide gas into the decompression chamber and at the same time, stopping the supply of the non-silicide gas; and a fourth step of forming a silicon film by radio frequency (high frequency) decomposing the silicide gas.

Although an amorphous silicon film is common as the silicon film, a microcrystalline silicon film or a crystalline silicon film may be formed.

In the above structure, it is important to make the pressure in the decompression chamber at the second step equal to the pressure in the decompression chamber at the fourth step. This is made to secure the stability of discharge at the step of starting the film formation.

If the pressure in the chamber at the second step is different from the pressure in the chamber at the fourth step, the state of discharge is changed at the time of start of the film formation (that is, at the initial state of the fourth step), so that the state where the discharge becomes unstable, is formed.

The unstable discharge state is extremely poor in reproducibility, and the continuing period thereof becomes different for each lot. This causes unevenness to the thickness of a formed film.

In the above-mentioned structure, in general, hydrogen is selected as the non-silicide gas, and silane is selected as the silicide gas. Other silicide gas such as disilane may be used as the silicide gas. A gas composed of silicide gas added with a minute amount of a doping gas such as diborane or phosphine may be used.

The non-silicide gas is a discharge gas which does not contain silicon. Helium in addition to hydrogen may be used as the non-silicide gas. It is important that the non-silicide gas is easily ionized, so that discharge easily takes place. Moreover, it is important that even if the non-silicide gas is contained in the silicon film, it does not have a very bad influence on the film quality.

In the above structure, the greater effect of the present invention can be obtained when the longest period of time t from the start of discharge of the second step to the time when the discharge becomes stable and the period of time T of film formation at the fourth step satisfy the relation of 10 t≧T.

For example, in the case where the period of time of film formation is sufficiently long, the unevenness of a continuing period of unstable discharge state at the start of discharge does not have a large influence on the film thickness. In this case, even if the present invention disclosed in the present specification is used, very large effects can not be obtained.

However, in the case where a thin film is formed so that the relation of 10 t≧T is satisfied, the unevenness of a continuing period of unstable discharge state at the start of discharge has a large influence on the film thickness. Thus, it is extremely effective to use the present invention disclosed in the present specification and to remove the influence at the start of the discharge from the film forming step.

The longest period of time t from the start of discharge at the second step to the time when the discharge becomes stable, means the largest value selected among uneven values of periods of time of unstable discharge obtained when plural times of discharge are carried out.

For example, in the case where ten times of discharge are carried out, it is assumed that the period of time (period of time in which the discharge is unstable) from the start of discharge to the time when the discharge becomes stable is uneven in the range of 4 to 7 seconds. In this case, 7 seconds is selected as the period of time t.

According to another aspect of the present invention, a film forming method comprises: a first step of supplying a non-product gas for discharge into a decompression chamber; a second step of supplying electromagnetic energy into the decompression chamber to cause discharge; a third step of supplying a product gas into the decompression chamber and at the same time, stopping the supply of the non-product gas; and a fourth step of forming a thin film by decomposing the product gas by the electromagnetic energy.

In the above structure, hydrogen is used as the non-product gas.

Radio frequency (high frequency) energy having a frequency selected from a band of MHz to GHz may be used as the electromagnetic energy.

In this case, the method of supplying the electromagnetic energy is not limited to the parallel flat plate type as shown in embodiments.

An example of forming a silicon film by using silane as the product gas, can be cited. However, an example of forming other semiconductor film or an insulating film may be cited.

In another aspect of the present invention disclosed in the present specification, attention is paid to the phenomenon that a self bias applied to an electrode on which a substrate is placed, disappears at the end of discharge, which causes minute particles to adhere to the surface of the substrate.

Thus, the present invention disclosed in the present specification is designed to make such a state that the discharge continues even after the end of the film formation.

The discharge is stopped after all minute particles existing in the atmosphere have been exhausted, so that the minute particles are prevented from adhering to the surface of a film.

That is, the state in which the self bias is formed as shown in FIG. 9, is maintained after the end of the film formation till the minute particles are exhausted.

In order to realize the foregoing state, in the present invention disclosed in the present specification, an atmosphere is changed from a film forming gas to a discharge gas while radio frequency (high frequency) discharge is continued.

By doing so, even after the supply of the film forming gas is ended and the film formation is ended, the discharge can be continued, and during the discharge, the state that the bias state as shown in FIG. 9 is maintained, can be continued.

By continuing this state for a while, the negatively charged minute particles in the atmosphere are exhausted outside while they are inhibited from adhering to the substrate.

In the state where the minute particles are exhausted to the outside, that is, in the state where the atmosphere is substituted, the radio frequency discharge is stopped, and further the supply of the discharge gas is stopped.

By this, it is possible to prevent the minute particles from adhering to the surface of the formed film.

Incidentally, the film forming gas means a gas containing a component of a film to be formed and containing a component constituting the minute particles.

As for the kinds of the film forming gas, when a silicon film is formed, silane and disilane may be cited, and when a hard carbon coated film is formed, methane may be cited.

The discharge gas means a gas which does not contribute to film formation or formation of minute particles by itself, but merely causes discharge and contributes to formation of plasma. As for the discharge gas, a hydrogen gas and a helium gas may be cited.

The kinds of a formed film are not specifically limited, and a general semiconductor film and an insulating film may be cited. The formed film may be a film of a compound.

According to a still another aspect of the present invention, a film forming method comprises a first step of forming a film by causing radio frequency (high frequency) discharge to form plasma in the state where a film forming gas is supplied; and a second step of forming plasma without forming a film by substituting the film forming gas with a discharge gas and continuing the radio frequency (high frequency) discharge.

In the above structure, it is important to maintain the pressure in the atmosphere at the first step and the pressure in the atmosphere at the second step at a constant. This is made so as not to change the condition under which the plasma is formed.

For example, if the pressure in the atmosphere is abruptly changed, abrupt discharge such as arc discharge occurs, so that the film quality of a formed film may be extremely damaged. As described above, in order to avoid such, the pressure in the atmosphere is maintained at the first step and the second step.

According to a still another aspect of the present invention, a film forming apparatus comprises first means for forming a film by causing radio frequency (high frequency) discharge to form plasma in the state where a film forming gas is supplied; and second means for forming plasma without forming a film by substituting the film forming gas with a discharge gas and continuing the radio frequency (high frequency) discharge.

In this structure, it is important to comprise means for maintaining a pressure in an atmosphere in the first means and a pressure in an atmosphere in the second means at a constant.

According to a still another aspect of the present invention, a method of forming a film by causing radio frequency (high frequency) discharge between parallel flat plate type electrodes and by a plasma vapor phase reaction, characterized in that the method is a vapor phase reaction method in which supply of a film forming gas is stopped in the state where a self bias is applied to a formed surface, and at the same time, a discharge gas is supplied so that the state where the self bias is applied to the formed surface is continued even after the end of film formation.

According to a still another aspect of the present invention, a film forming apparatus for forming a film by causing radio frequency (high frequency) discharge between parallel flat plate type electrodes and by a plasma vapor phase reaction, characterized in that the film forming apparatus comprises means for stopping supply of a film forming gas in a state where a self bias is applied to a formed surface, and at the same time, supplying a discharge gas so that the state where the self bias is applied to the formed surface is continued even after the end of film formation.

### BRIEF DESCRIPTION OF THE DRAWINGS

FIG. 1 is a view schematically showing a plasma CVD apparatus.

FIGS. 2A and 2B are views showing timing charts at film formation.

FIGS. 3A to 3D are views showing manufacturing steps of a TFT.

FIGS. 4A to 4C are views showing manufacturing steps of the TFT.

FIG. 5 is a view showing the timing between the supply of a gas and the supply of radio frequency (RF) power (high frequency power).

FIG. 6 is a view showing the timing between the supply of a gas and the supply of radio frequency (RF) power (high frequency power).

FIG. 7 is a view showing the timing between the supply of a gas and the supply of radio frequency (RF) power (high frequency power).

FIG. 8 is a view showing the timing between the supply of a gas and the supply of radio frequency (RF) power (high frequency power) in prior art.

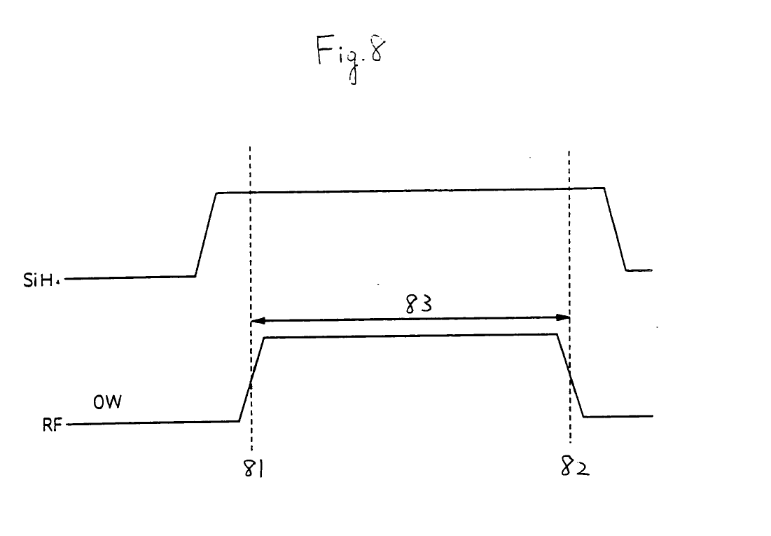

FIG. 9 is a view showing the state of a self-bias during radio frequency (RF) discharge (high frequency discharge).

### DETAILED DESCRIPTION OF THE PREFERRED EMBODIMENTS

The gist of the present invention will first be described.

When an amorphous silicon film is formed by a plasma CVD method, a hydrogen gas is supplied into a chamber before the start of film formation, and discharge is caused. Film formation has not yet been carried out in this state.

At the step where the discharge becomes stable, silane as a film forming gas is supplied into the chamber. At the same time, the supply of the hydrogen gas is stopped. Silane is decomposed by the stable discharge to form an amorphous silicon film.

By doing so, the instability at the start of the discharge can be removed. The film formation can always be made in the state where the discharge is stable.

By this method, the start of film formation does not vary for each lot, and the film formation can be started at the same timing. It is also possible to suppress the hydrogen gas used at the start of discharge from affecting the film quality.

Especially in the case where the obtained amorphous silicon film is crystallized, it is extremely important to prevent hydrogen from being contained in the foregoing film.

As the method of crystallization, although a method of heating, or a method of irradiation of laser light or intense light may be cited, in any case, it has been found that the presence of excess hydrogen contained in the amorphous silicon film hinders the crystallization.

Thus, in the case where a step of crystallization follows, as described above, it is important to stop the supply of the hydrogen gas at the same time as the start of the supply of the silane gas to prevent hydrogen from mixing into the film.

Further, in the film formation of the amorphous silicon film by the plasma CVD method using silane as the film forming gas, the silane gas is substituted with the hydrogen gas at the end of the film formation. At this time, the radio frequency discharge is continued.

By doing so, it is possible to continue the state where a negative bias is applied to a formed surface even after the end of the film formation. The discharge by the hydrogen gas is continued for a while till minute particles as negatively charged reaction products are exhausted outside of the atmosphere, so that it is possible to prevent the minute particles from adhering to the formed surface.

Preferred embodiments of the present invention will next be described.

### Embodiment 1

(Explanation of a Film Forming Apparatus)

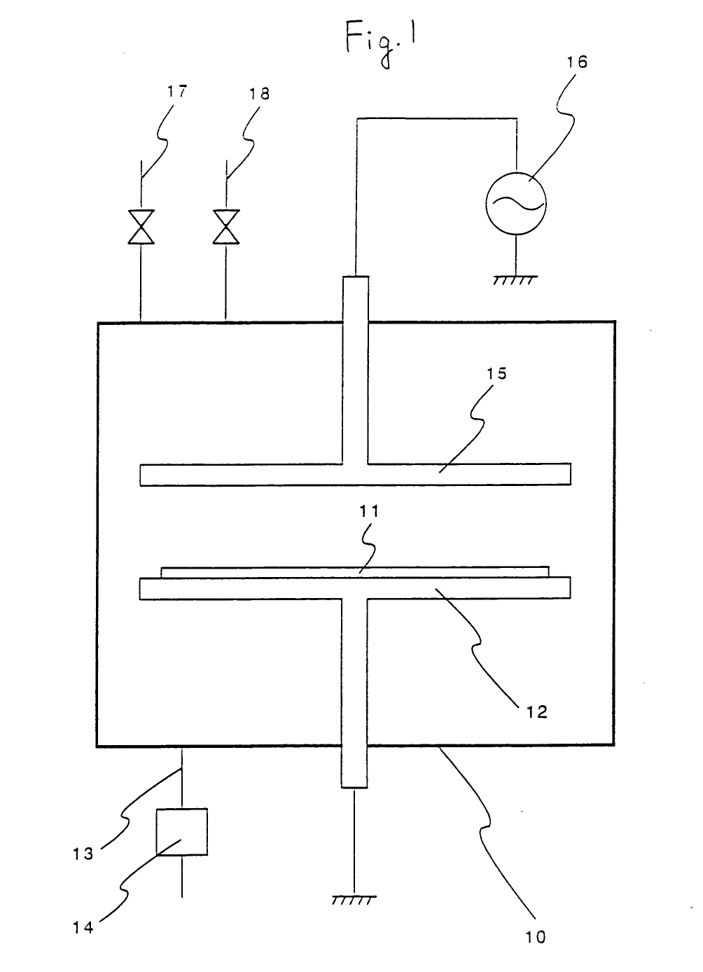

First, the outline of a film forming apparatus used in embodiments of the present invention will be described. FIG. 1 schematically shows a plasma CVD apparatus for forming an amorphous silicon film.

This apparatus includes a pair of parallel flat plate electrodes 12 and 15 in the inside of a decompression chamber 10 made of stainless.

A substrate (sample) 11 is placed on the one electrode 12 connected to ground potential. A radio frequency (high frequency) power source 16 is connected to the other electrode 15. Although not shown in the drawing, a matching circuit is disposed between the electrode 15 and the radio frequency (high frequency) power source 16.

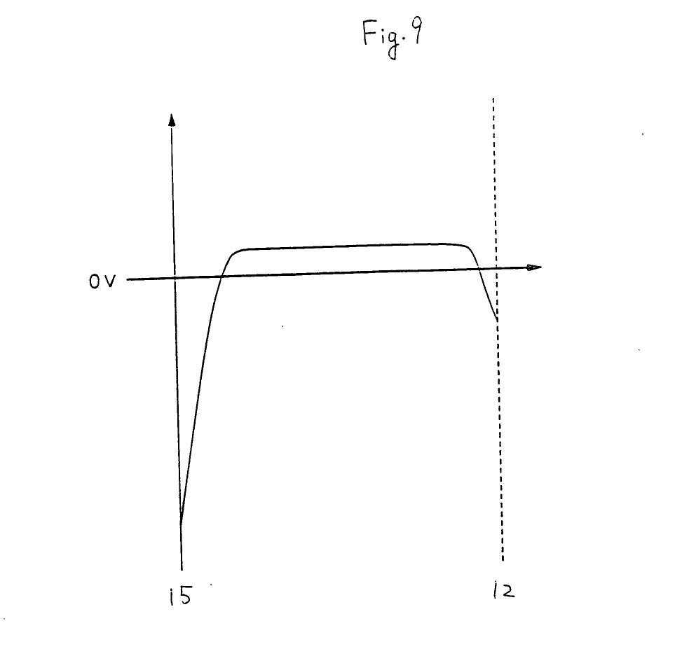

The radio frequency (high frequency) power source has a function to generate radio frequency (high frequency) power of a required output. As a frequency of the radio frequency (high frequency) power, 13.56 MHz is generally used. Of course, other frequency may be used. However, the frequency must satisfy the condition that the self bias as shown in FIG. 9 is formed.

The decompression chamber 10 is provided with gas supply systems 17 and 18 for supplying gas into the inside thereof.

Reference numeral 17 denotes a gas line for supplying a silane gas, and 18 denotes a gas line for supplying a hydrogen gas.

Further, the decompression chamber 10 is provided with an exhaust system 13 having an exhaust pump 14 for evacuating the inside into a required decompressed state.

Although not shown, the decompression chamber 10 is provided with a door for inserting a substrate from the outside into the apparatus.

In this embodiment, a rectangular electrode with an area of 490 cm² is disposed. The radio frequency electric power with a frequency of 13.56 MHz and an output of 20 W is supplied to the electrode 15 from the radio frequency (high frequency) power source 16 through the not-shown matching circuit.

(Film Forming Method of an Amorphous Silicon Film)

Here, by using the method disclosed in the present specification, an example of forming an amorphous silicon film will be described.

First, the not-shown door fitted to the decompression chamber is opened and the substrate 11 is inserted into the chamber. The substrate 11 is placed on the electrode 12 connected to the ground potential.

Next, the not-shown door is closed, and the decompression chamber 10 is brought into an airtightly sealed state. Then the exhaust pump 14 is operated to bring the inside of the decompression chamber 10 into a decompressed state.

Here, it is preferable that a nitrogen gas is supplied from a not-shown gas supply system to remove impurities in the chamber, and the inside of the chamber is once filled with the nitrogen gas, and then the inside of the decompression chamber 10 is brought into the decompressed state.

In this step, it is preferable to bring the inside of the chamber 10 into the highest possible vacuum state.

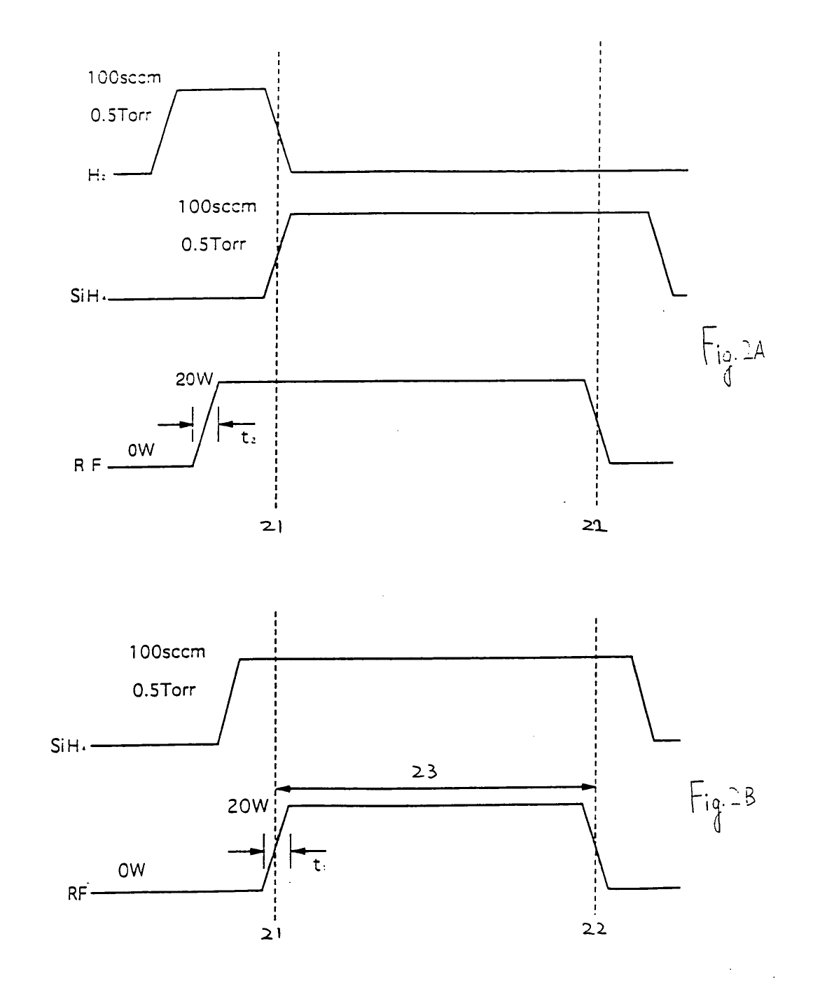

Next, in accordance with the timing chart shown in FIG. 2A, an amorphous silicon film is formed on the substrate 11.

First, the inside of the decompression chamber 10 is brought into an ultra high vacuum state (state where the highest possible exhaust was carried out). Then a hydrogen gas of a flow rate of 100 sccm is supplied from the gas supply system 18. In this condition, the pressure in the decompression chamber 10 becomes 0.5 Torr (the relation between a flow rate and a pressure depends on the volume of a chamber and the capacity of an exhaust pump).

In the state where the pressure in the chamber 10 becomes a predetermined value, the radio frequency (high frequency) power (output of 20 W) is supplied from the radio frequency (high frequency) power source 16.

At this time, the period of time indicated by t₂ in which the unstable discharge state at the start of discharge continues, becomes uneven for each lot.

The period of time t₂ becomes uneven within the range of about 2 seconds to 8 seconds. Thus, in this embodiment, supply of silane (SiH₄) into the chamber 10 is started after 10 seconds from the start of the discharge.

By doing so, it is possible to supply silane into the chamber 10 after the discharge has become stable without fail.

At the same time as the start of the supply of silane, the supply of hydrogen is stopped. At this time, it is important to set start timing of supply of silane, a period of time in which the flow rate of silane becomes stable, stop timing of supply of hydrogen, and a period of time in which the flow rate of hydrogen is changed, so that the total amount of gas supplied into the inside of the chamber 10 does not change.

By doing so, it is possible to prevent the change of pressure in the atmosphere at the time when the supply of the hydrogen gas is converted to the supply of the silane gas.

The termination of film formation is made by stopping the supply of the radio frequency (high frequency) power to stop the discharge.

In the case where the timing chart as shown in FIG. 2A is adopted, it is possible to stabilize the discharge at the step of supplying silane. Thus, it is possible to solve the problem that a period of time of film formation becomes uneven for each lot.

In this embodiment, the supply of the hydrogen gas is stopped at the step of starting the supply of the silane gas. This is made to suppress the lowering of film quality of the amorphous silicon film which is otherwise caused by excess hydrogen taken into the formed amorphous silicon film.

The film formation method shown in FIG. 2A is characterized in that the timing of start of discharge is shifted from the start of film formation so that the instability at the start of discharge does not have an influence on the film formation.

Such a film formation method becomes effective in the case where the longest period of time t from the start of discharge to the time when the discharge becomes stable is 10% or more of the period of time T of film formation.

That is, the method becomes effective in the case where a period of time of film formation is short and the instability at the initial stage of discharge continues for a period of time which can not be neglected for the period of time of film formation.

### Embodiment 2

Here, an example in which an amorphous silicon film is formed by using another method disclosed in the present specification, will be described.

First, the not-shown door fitted to the decompression chamber is opened, and the substrate 11 is carried in the chamber 10. The substrate 11 is placed on the electrode 12 connected to the ground potential.

Next, the not-shown door is closed, and the decompression chamber 10 is brought into an airtightly sealed state. Then the exhaust pump 14 is operated so that the inside of the decompression chamber 10 is brought into a decompressed state.

Here, in order to remove impurities in the chamber, it is preferable that a nitrogen gas is supplied from a not-shown gas supply system to once fill the inside of the chamber with the nitrogen gas, and then the inside of the decompression chamber 10 is brought into the decompressed state.

It is preferable at this stage to bring the inside of the chamber 10 into the highest possible vacuum state.

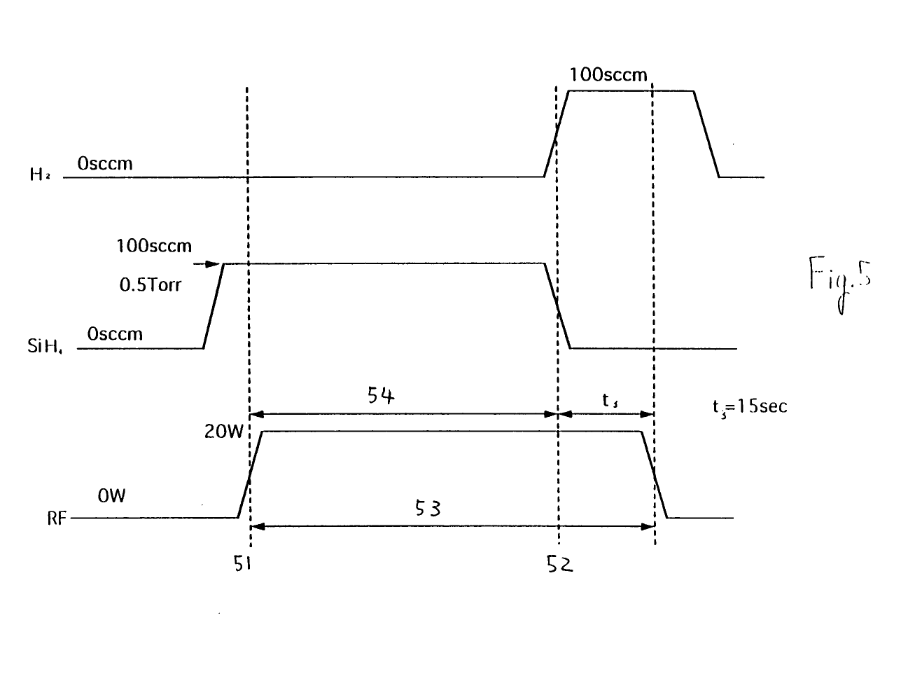

Next, in accordance with the timing chart shown in FIG. 5, an amorphous silicon film is formed on the substrate 11. Incidentally, reference numeral 51 denotes a start point of film formation, 52 denotes an end point of film formation, 53 denotes a period of time of discharge, and 54 denotes a period of time of film formation.

First, the inside of the decompression chamber 10 is brought into an ultra high vacuum state (state in which the highest possible exhaust was made). Then a silane gas (SiH₄ gas) is supplied from the gas supply system 17 at a flow rate of 100 sccm. In this embodiment, under this condition, the pressure in the decompression chamber 10 becomes 0.5 Torr (the relation between a flow rate and a pressure depends on the volume of a chamber and the capacity of an exhaust pump).

In the state where the pressure in the chamber 10 becomes a predetermined value, the radio frequency power (RF power) (output of 20 W) is supplied from the radio frequency (high frequency) power source 16.

The time when the supply of the radio frequency (high frequency) power is started, can be regarded as the start point of film formation.

The termination of film formation is made by stopping the supply of the silane gas. Here, at the same time as the stop of supply of the silane gas, the supply of a hydrogen gas is carried out from the gas system 18.

The supply of the hydrogen gas is made 100 sccm. This value is selected so that the pressure change in the chamber due to the conversion of gas is made as small as possible.

By doing so, it is possible to stop the film formation in the state where the discharge is maintained (state where plasma is produced).

In this embodiment, the timing of conversion is set so that the pressure change due to the conversion of gas is as little as possible.

Here, a period of time of a transitional state due to the stop of the silane gas is set equal to a period of time of a transitional state due to the start of supply of the hydrogen gas, and further both the transitional states are overlapped with each other. The period of time of the transitional time is 2 seconds.

When the supply of the silane gas is stopped, the film formation is ended. The discharge with the hydrogen gas is continued for a predetermined period of time t₃.

The value of t₁ depends on the volume of the chamber and the capacity of gas supply, and further the capacity of the exhaust system and the like.

It is important that the value of t₃ is made larger than a period of time (indicated by t₃′) in which the gas in the chamber is substituted. That is, t₃>t₃′.

By doing so, it is possible to make the state where minute particles do not exist in the atmosphere in the state where the discharge is stopped, and it is possible to prevent the minute particles from adhering to the surface of the formed film.

If the foregoing relation indicated by t₃>t₃′ is not satisfied, the state where the minute particles are floating in the atmosphere after the discharge is stopped, is realized, so that the minute particles adhere to the surface of the film. In this case, the effects of the present invention can not be obtained.

After the discharge is stopped, the supply of the hydrogen gas is stopped. In this way, the step of film formation is ended.

The film formation method shown in FIG. 5 is characterized in that the timing of stop of film formation is shifted from the timing of stop of discharge. That is, even after the film formation is ended, the discharge is continued to maintain the formation of plasma which has no influence on the film formation, so that the self bias as shown in FIG. 9 is formed.

By doing so, it is possible to prevent the minute particles from adhering to the film after the end of film formation.

### Embodiment 3

In this embodiment, manufacturing steps of a thin film transistor using a film formation method of an amorphous silicon film shown in the embodiment 1 or embodiment 2, will be described.

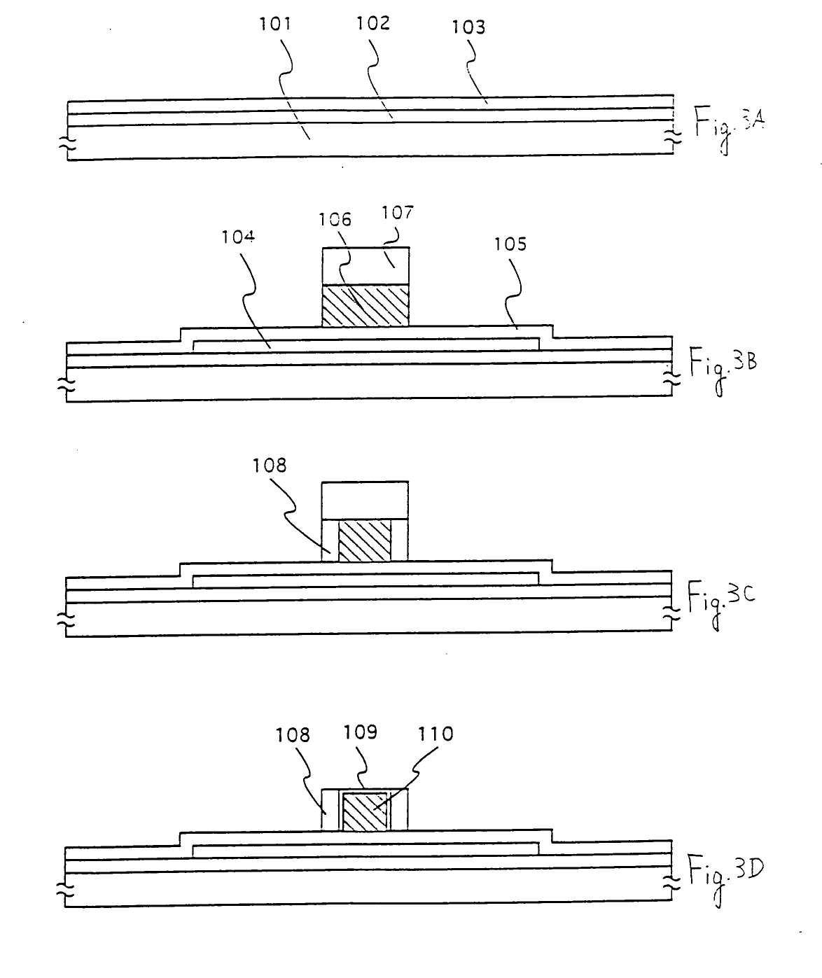

FIGS. 3A to 3D show the manufacturing steps of this embodiment. First, as shown in FIG. 3A, a silicon oxide film 102 with a thickness of 300 nm as an under film is formed on a glass substrate 101 by a plasma CVD method.

Next, by the method shown in the embodiment 1 or the embodiment 2, an amorphous silicon film 103 with a thickness of 50 nm is formed. In this way, the state shown in FIG. 3A is obtained.

Next, irradiation of laser light is carried out to crystallize the amorphous silicon film 103. A method of heating, a combination of heating and irradiation of intense light, a combination of heating and irradiation of laser light, and the like may be used as a method of crystallizing the amorphous silicon film.

Next, the thus obtained crystalline silicon film is patterned to obtain a pattern indicated by 104 in FIG. 3B. Further, a silicon oxide film 105 with a thickness of 100 nm functioning as a gate insulating film is formed by the plasma CVD method.

Further, an aluminum film with a thickness of 400 nm is formed by a sputtering method. The aluminum film is patterned by using a resist mask 107. In this way, a pattern 106 is obtained. This pattern 106 becomes a base for subsequently forming a gate electrode.

In this way, the state shown in FIG. 3B is obtained. Next, anodic oxidation with the aluminum pattern 106 as an anode is carried out while the resist mask 107 remains. Here, a solution containing oxalic acid of 3 vol % is used as an electrolyte, and the anodic oxidation is carried out while using the pattern 106 as an anode, and platinum as a cathode.

In this step, since the resist mask 107 exists, an anodic oxidation film 108 is formed at the side surface of the aluminum pattern 106 in the state as shown in FIG. 3C.

The film thickness of this anodic oxidation film is made 400 nm. The anodic oxidation film formed in this step is a porous film.

After the state shown in FIG. 3C is obtained, the resist mask 107 is removed. Then anodic oxidation is again carried out. Here, an ethylene glycol solution containing tartaric acid of 3 vol % neutralized with aqueous ammonia is used as an electrolyte.

In this step, since the electrolyte is infiltrated into the inside of the porous anodic oxidation film 108, an anodic oxidation film 109 shown in FIG. 3D is formed. The thickness of the anodic oxidation film 109 is made 70 nm. Here, a pattern indicated by 110 becomes a gate electrode.

The anodic oxidation film 109 formed in this step becomes a film having dense film quality.

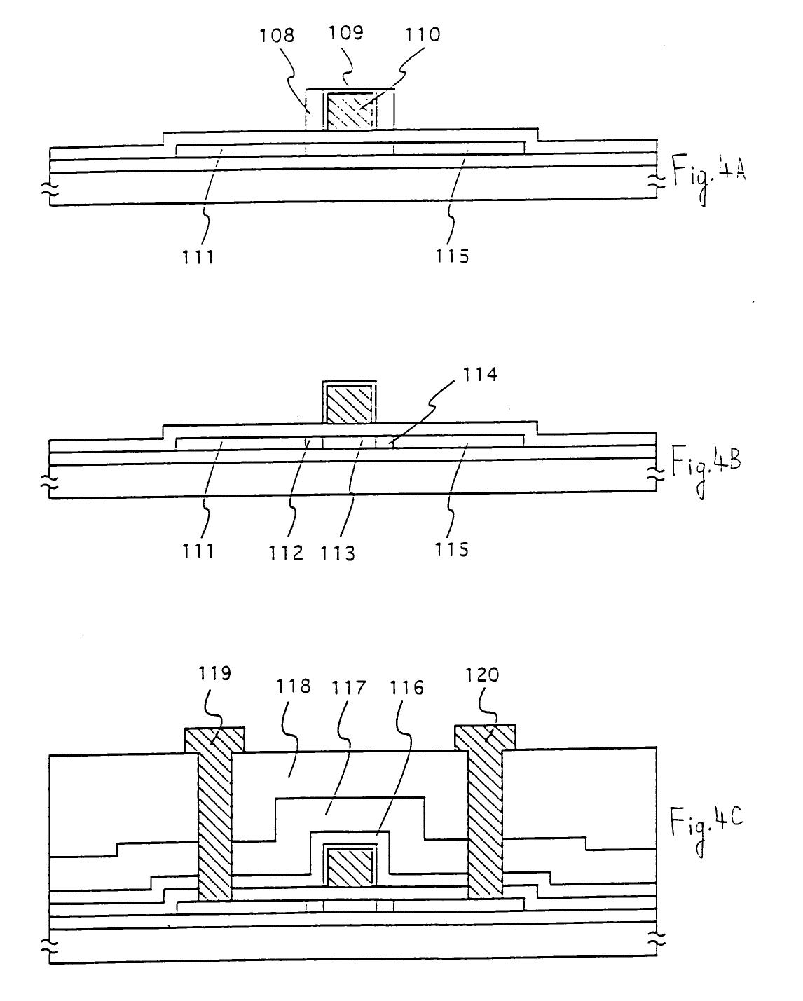

In this way, the state shown in FIG. 3D is obtained. Next, doping of impurity elements is carried out in the state shown in FIG. 4A. Here, in order to fabricate an N-channel TFT, doping of phosphorus is carried out by a plasma doping method.

Here, the plasma doping method is used in which phosphorus ions are extracted by an electric field from plasma containing phosphorus ions, and the ions are electrically accelerated to carry out doping. However, an ion implantation method in which phosphorus ions are electrically accelerated and implanted after mass separation has been carried out, may be used as a doping means.

This doping is carried out under the conditions where normal source and drain regions are formed. In this way, doping of phosphorus is carried out in regions 111 and 115 in a self-aligned manner as shown in FIG. 4A. Here, the region 111 becomes the source region, and the region 115 becomes the drain region.

Next, the porous anodic oxidation film 108 is removed, and the state shown in FIG. 4B is obtained. Then doping of phosphorus is again carried out by the plasma doping method.

This doping is carried out under the condition of light doping as compared with the previous doping carried out in the state shown in FIG. 4A.

In this step, low concentration impurity concentration regions 112 and 114 are formed in a self-aligned manner. A region 113 is defined as a channel formation region (FIG. 4B). Here, the low concentration impurity concentration means that the concentration of a dopant (phosphorus in this case) is lower than that of the source region 111 and the drain region 115.

After the doping is ended, irradiation of laser light is carried out, so that the crystallinity of the region where the doping was carried out is improved and the dopant is activated.

Here, although an example of irradiation of laser light is shown, a method of irradiation of intense light may be used.

Next, as shown in FIG. 4C, a silicon nitride film 116 with a thickness of 150 nm is formed by the plasma CVD method, and further a silicon oxide film 117 with a thickness of 400 nm is formed by the plasma CVD method.

Further, acrylic resin is applied to form a resin film 118. When the resin film is used, the surface thereof can be made flat. Other than the acrylic resin, resin materials such as polyimide, polyimide amide, polyamide, and epoxy may be used.

Next, contact holes are formed, and a source electrode 119 and a drain electrode 120 are formed. In this way, a TFT is completed.

In this embodiment, an example in which the glass substrate is used as a substrate, has been described. However, other than the glass substrate, a quartz substrate, a semiconductor substrate having an insulating film formed thereon, or a metal substrate having an insulating film formed thereon may be used (these will be referred to generally as a substrate having an insulating surface).

In this embodiment, although an example in which a semiconductor film constituting the active layer of the TFT is a crystalline silicon film, has been described, the active layer may be constituted by an amorphous silicon film.

Further, in this embodiment, although an example in which aluminum is used as the gate electrode, has been described, other materials such as a silicon material and a silicide material, and further a suitable metal material may be used.

Further, in this embodiment, although an example of a top-gate type TFT in which a gate electrode is positioned over an active layer, has been described, a bottom-gate type TFT in which a gate electrode is positioned under (substrate side) an active layer, may be used.

### Embodiment 4

This embodiment shows an example in which the structure shown in the embodiment 2 is further improved.

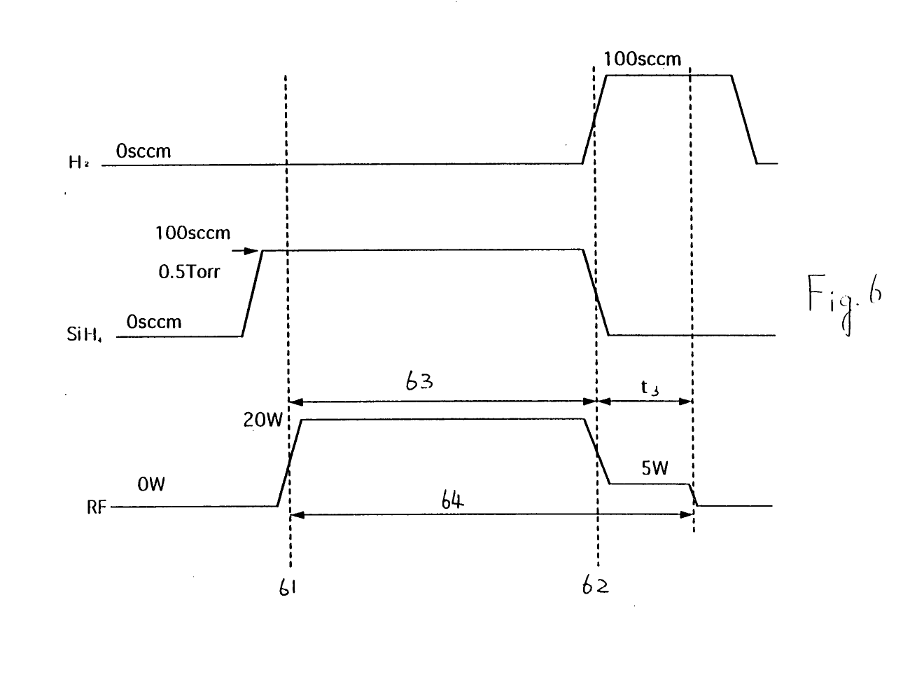

In this embodiment, film formation is carried out in accordance with the timing chart shown in FIG. 6. In FIG. 6, 61 denotes a start point of film formation, 62 denotes an end point of film formation, 63 denotes a period of time of film formation, and 64 denotes a period of time of discharge. It is important in the timing chart of FIG. 6 to phase down (stepwise reduce) the discharge power in the discharge after the end of film formation (that is, after the stop of supply of silane gas).

By doing so, it is possible to prevent the minute particles attached to the inner wall of a chamber from being released into the atmosphere. It is also poss-ble to prevent plasma damage from being exerted to a formed film.

Here, an example in which the discharge power of 20 W is lowered to 5 W after the end of film formation (after the stop of supply of the silane gas), has been described.

The manner of change of the discharge power may be carried out in a further step-like manner. Moreover, a continuous change may be adopted. Also, the combination of the step-like change and the continuous change may be adopted.

### Embodiment 5

This embodiment relates to a structure in which the start of discharge is taken into consideration in the structure shown in the embodiment 2. That is, this embodiment relates to the structure of the combination of the embodiment 1 and the embodiment 2.

When film formation is carried out at the timing which is described in the embodiment 2 and is shown in FIG. 5, the start of discharge coincides with the start of film formation. That is, in this case, the film formation is started by starting the discharge. In other words, the film formation is started at the same time as the start of generation of plasma.

However, according to the difference of electrode structure or the like, there is a case where a period of time of unstable discharge continues for several seconds at the start of discharge.

In order to suppress this problem, in this embodiment, the atmosphere is first made a discharge gas, and discharge is made at this state. Next, gas is changed to a film forming gas, and film formation is made in the state where the discharge is continued.

If an amorphous silicon film is formed, hydrogen is used as the discharge gas, and silane is used as the film forming gas.

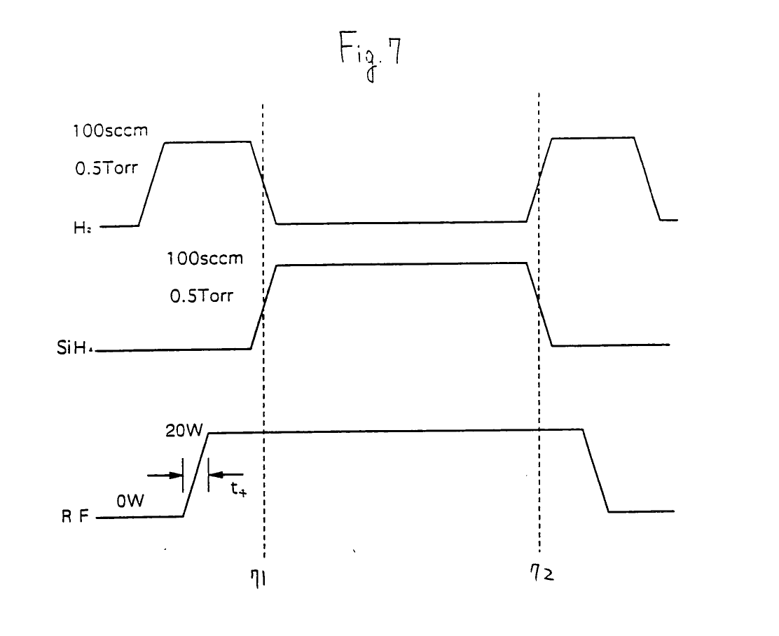

FIG. 7 shows a timing chart in the case where film formation in this embodiment is carried out. Reference numeral 71 denotes a start point of film formation, and 72 denotes an end point of film formation. Also in this embodiment, it is preferable that the pressure change in the atmosphere due to conversion of gas is as small as possible.

When film formation is carried out at the timing as shown in FIG. 7, it is possible to prevent the instability of discharge in a period indicated by t₄ at the start of discharge from affecting the film formation.

As shown in FIG. 7, in this embodiment, a hydrogen gas as the discharge gas is introduced for only generating discharge (for only generating plasma) immediately before the start of film formation and immediately after the end of film formation.

By doing so, it is possible to prevent the instability at the start of discharge from affecting the film formation and to prevent minute particles after film formation from adhering to the surface of the film.

### Embodiment 6

In this embodiment, an example in which a hard carbon film typified by a DLC film (Diamond-like Carbon film) is formed, will be described.

As the kinds of the hard carbon film, a variety of kinds exist other than the DLC film, and a method of classification or an estimation has not been determined. Then, in this embodiment, a carbon film used as a protective film or a coating film having wear resistance will be referred to generally as a hard carbon film.

In the case where the hard carbon film is formed, there is used a method in which film formation is carried out by using a strong self bias to cause carbon ions to hit on a formed surface.

In such a film forming method, the formed surface is disposed on the side of the electrode 15 connected to the radio frequency power source 16 of the plasma CVD apparatus as shown in FIG. 1.

That is, the substrate 11 (or a base material instead thereof) is disposed at the side of the electrode 15.

Also in such a structure, the present invention disclosed in the present specification is useful. That is, when the film formation is carried out in accordance with the timing chart as shown in FIG. 5, it is possible to prevent the minute particles from adhering to the surface of a formed film.

Also in this case, the self bias according to the formation of plasma is made to apply to the formed surface after the end of film formation, and further the discharge is stopped in the state where the atmosphere in the chamber is substituted, so that it is possible to prevent the minute particles from adhering to the formed surface.

### Embodiment 7

This embodiment shows a case where the present invention disclosed in the present specification is used for continuous film formation.

In a multichamber type film formation apparatus in which a plurality of film formation chambers are coupled to each other in series or in parallel, when different films are laminated into a multilayer, especially the existence of minute particles remaining on the film as an under layer becomes a problem.

Then, for example, the method as shown in the embodiment 2 is carried out for each film formation. By doing so, the foregoing problem can be solved.

In the above description, on the basis of the embodiment 1 or the embodiment 2, its variation has been described. However, the respective embodiments may be combined according to necessity.

As described above, by using the present invention as disclosed in the present specification, it is possible to solve the problem due to the instability of discharge at the start of film formation, and it is possible to correct the unevenness of film thickness for each lot.

Further, by using the present invention disclosed in the present specification, it is possible to prevent the existence of minute particles of reaction products produced at film formation in the plasma CVD method from having a bad influence on the film quality of a formed thin film.

What is claimed is:

1. A method for manufacturing a thin film device comprising:
supplying a discharge gas into a chamber;
supplying radio frequency energy in the chamber to generate plasma from the discharge gas by radio frequency discharge;
supplying a reactive gas into the chamber by increasing a flow rate of the reactive gas;
stopping the discharge gas by decreasing a flow rate of the discharge gas; and
forming a film over a substrate in the chamber by decomposing the reactive gas using the radio frequency energy,
wherein a start of increasing the flow rate of the reactive gas is simultaneous with a start of decreasing the flow rate of the discharge gas, and
wherein an end of increasing the flow rate of the reactive gas is simultaneous with an end of decreasing the flow rate of the discharge gas.

2. A method for manufacturing a thin film device according to claim 1, wherein the discharge gas contains hydrogen.

3. A method for manufacturing a thin film device according to claim 1, wherein the reactive gas contains silane.

4. A method for manufacturing a thin film device according to claim 1, wherein the flow rate of the discharge gas is 100 sccm.

5. A method for manufacturing a thin film device according to claim 1, wherein the flow rate of the reactive gas is 100 sccm.

6. A method for manufacturing a thin film device according to claim 1, wherein the thin film device includes a thin film transistor.

7. A method for manufacturing a thin film device comprising:
supplying a discharge gas into a chamber;
supplying radio frequency energy in the chamber to generate plasma from the discharge gas by radio frequency discharge;
supplying a reactive gas into the chamber by increasing a flow rate of the reactive gas;
stopping the discharge gas by decreasing a flow rate of the discharge gas; and
forming a semiconductor film over a substrate in the chamber by decomposing the reactive gas using the radio frequency energy,
wherein a start of increasing the flow rate of the reactive gas is simultaneous with a start of decreasing the flow rate of the discharge gas, and
wherein an end of increasing the flow rate of the reactive gas is simultaneous with an end of decreasing the flow rate of the discharge gas.

8. A method for manufacturing a thin film device according to claim 7, wherein the discharge gas contains hydrogen.

9. A method for manufacturing a thin film device according to claim 7, wherein the reactive gas contains silane.

10. A method for manufacturing a thin film device according to claim 7, wherein the flow rate of the discharge gas is 100 sccm.

11. A method for manufacturing a thin film device according to claim 7, wherein the flow rate of the reactive gas is 100 sccm.

12. A method for manufacturing a thin film device according to claim 7, wherein the semiconductor film is an amorphous silicon.

13. A method for manufacturing a thin film device according to claim 7, wherein the thin film device includes a thin film transistor.

14. A method for manufacturing a thin film device comprising:
supplying a discharge gas into a chamber;
supplying radio frequency energy in the chamber to generate plasma from the discharge gas by radio frequency discharge;
supplying a reactive gas into the chamber by increasing a flow rate of the reactive gas;
stopping the discharge gas by decreasing a flow rate of the discharge gas; and
forming an insulating film over a substrate in the chamber by decomposing the reactive gas using the radio frequency energy,
wherein a start of increasing the flow rate of the reactive gas is simultaneous with a start of decreasing the flow rate of the discharge gas, and
wherein an end of increasing the flow rate of the reactive gas is simultaneous with an end of decreasing the flow rate of the discharge gas.

15. A method for manufacturing a thin film device according to claim 14, wherein the discharge gas contains hydrogen.

16. A method for manufacturing a thin film device according to claim 14, wherein the reactive gas contains silane.

17. A method for manufacturing a thin film device according to claim 14, wherein the flow rate of the discharge gas is 100 sccm.

18. A method for manufacturing a thin film device according to claim 14, wherein the flow rate of the reactive gas is 100 sccm.

19. A method for manufacturing a thin film device according to claim 14, wherein the thin film device includes a thin film transistor.

20. A method for manufacturing a thin film device comprising:
forming a film over a substrate in a chamber by decomposing a reactive gas using radio frequency energy;
stopping the reactive gas by decreasing a flow rate of the reactive gas;
supplying a discharge gas into the chamber by increasing a flow rate of the discharge gas; and
stopping the radio frequency energy after supplying the discharge gas into the chamber,
wherein a start of decreasing the flow rate of the reactive gas is simultaneous with a start of increasing the flow rate of the discharge gas, and
wherein an end of decreasing the flow rate of the reactive gas is simultaneous with an end of increasing the flow rate of the discharge gas.

21. A method for manufacturing a thin film device according to claim 20, wherein the discharge gas contains hydrogen.

22. A method for manufacturing a thin film device according to claim 20, wherein the reactive gas contains silane.

23. A method for manufacturing a thin film device according to claim 20, wherein the flow rate of the discharge gas is 100 sccm.

24. A method for manufacturing a thin film device according to claim 20, wherein the flow rate of the reactive gas is 100 sccm.

25. A method for manufacturing a thin film device according to claim 20, wherein the thin film device includes a thin film transistor.

26. A method for manufacturing a thin film device comprising:
forming a semiconductor film over a substrate in a chamber by decomposing a reactive gas using radio frequency energy;
stopping the reactive gas by decreasing a flow rate of the reactive gas;
supplying a discharge gas into the chamber by increasing a flow rate of the discharge gas; and
stopping the radio frequency energy after supplying the discharge gas into the chamber,
wherein a start of decreasing the flow rate of the reactive gas is simultaneous with a start of increasing the flow rate of the discharge gas, and
wherein an end of decreasing the flow rate of the reactive gas is simultaneous with an end of increasing the flow rate of the discharge gas.

27. A method for manufacturing a thin film device according to claim 26, wherein the discharge gas contains hydrogen.

28. A method for manufacturing a thin film device according to claim 26, wherein the reactive gas contains silane.

29. A method for manufacturing a thin film device according to claim 26, wherein the flow rate of the discharge gas is 100 sccm.

30. A method for manufacturing a thin film device according to claim 26, wherein the flow rate of the reactive gas is 100 sccm.

31. A method for manufacturing a thin film device according to claim 26, wherein the semiconductor film is an amorphous silicon.

32. A method for manufacturing a thin film device according to claim 26, wherein the thin film device includes a thin film transistor.

33. A method for manufacturing a thin film device comprising:
forming an insulating film over a substrate in a chamber by decomposing a reactive gas using radio frequency energy;
stopping the reactive gas by decreasing a flow rate of the reactive gas;
supplying a discharge gas into the chamber by increasing a flow rate of the discharge gas; and
stopping the radio frequency energy after supplying the discharge gas into the chamber,
wherein a start of decreasing the flow rate of the reactive gas is simultaneous with a start of increasing the flow rate of the discharge gas, and
wherein an end of decreasing the flow rate of the reactive gas is simultaneous with an end of increasing the flow rate of the discharge gas.

34. A method for manufacturing a thin film device according to claim 33, wherein the discharge gas contains hydrogen.

35. A method for manufacturing a thin film device according to claim 33, wherein the reactive gas contains silane.

36. A method for manufacturing a thin film device according to claim 33, wherein the flow rate of the discharge gas is 100 sccm.

37. A method for manufacturing a thin film device according to claim 33, wherein the flow rate of the reactive gas is 100 sccm.

38. A method for manufacturing a thin film device according to claim 33, wherein the thin film device includes a thin film transistor.
